(19) United States
(12) Patent Application Publication
(10) Pub. No.: US 2018/0342853 A1
(43) Pub. Date: Nov. 29, 2018

(54) ASSEMBLY AND METHOD FOR MONITORING OUTPUT OF A LIGHT EMITTING SOURCE

(71) Applicant: Mellanox Technologies Denmark ApS., Roskilde (DK)

(72) Inventor: Søren Balslev, Jægerspris (DK)

(21) Appl. No.: 15/602,232

(22) Filed: May 23, 2017

(51) Int. Cl. H01S 5/068; H01S 5/42; H04B 10/50

(52) U.S. Cl. CPC H01S 5/06825; G02B 6/4286; H04B 10/503; H01S 5/423

(57) ABSTRACT

Assemblies and methods are described that provide for monitoring output from light emitting sources, such as vertical-cavity surface-emitting lasers. In particular, the assembly includes an array of light emitting sources, an array of lenses, an array of photodiodes, and a controller. The light is emitted by the array of light emitting sources, which in turn is configured to emit light towards the array of lenses. A photo-induced current is generated at the array of photodiodes, which is arranged to receive light reflected off of the array of lenses. The assembly determines a change in operational status of one or more of the light emitting sources based on the photo-induced currents.

### TECHNICAL FIELD

Embodiments of the present invention relate generally to decreasing the cost and increasing the reliability of optical communication networks. More specifically, embodiments of the present invention monitor the output of light emitting sources and detect failure or potential failure of the light emitting sources.

### BACKGROUND

Operators of optical networks including fiber optic communication networks often want to know the operational status of various systems and system components in the network, including the functional status of optical communication components such as optical transmitters, receivers, and transceivers. Knowing the operational status aids the operators in identifying components of the network that may need to be repaired or replaced. In the case of transmitters/transceivers in optical communications, the light producing components (sources), such as vertical-cavity surface-emitting lasers (VCSELs), may begin to malfunction or not emit light that meets the designed capabilities of the VCSEL or corresponds to the power being supplied to the VCSEL.

### BRIEF SUMMARY

Embodiments of the present invention utilize an array of light emitting sources, an array of photodiodes, and a controller to measure the light produced by the light emitting sources and detect potential failures of the light emitting sources. In one example embodiment, an assembly for monitoring output of a light emitting source (LES) is provided. The assembly includes an array of lenses, an array of LESs, wherein each LES is configured to emit light towards a lens in the array of lenses, an array of photodiodes, arranged to receive light reflected off of the array of lenses, wherein each photodiode is configured to generate a photo-induced current in response to receipt of the light reflected off the array of lenses, and a controller. In some examples, the controller is configured to measure the photo-induced current from each photodiode in the array of photodiodes, and determine a change in operational status of one or more of the LESs based on the photo-induced currents.

In some cases, the array of LESs and the array of photodiodes form a coupled pair, and the controller is further configured to receive a value indicative of a power consumption of each LES, correlate the power consumption of each LES with a measured photo-induced current in each photodiode, determine a coupling matrix for the coupled pair, and determine an inverted matrix by inverting the coupling matrix.

In some examples, the controller is further configured to determine a photo-induced current matrix from updated measured photo-induced currents from each photodiode, and multiply the inverted matrix and the photo-induced current matrix to form a LES output matrix, wherein the LES output matrix represents an ongoing light output from each LES.

In some cases, the controller is further configured to determine, from the LES output matrix, one or more LESs experiencing a failure event based on an ongoing light output lower than a predetermined expected value from the one or more LESs.

Additionally, in some examples, the failure event comprises a failing LES and the lower ongoing light output comprises a light output lower than a predetermined expected value.

In some cases, the failure event comprises a failed LES and the lower ongoing light output comprises no light output.

In some examples, a position of the array of photodiodes relative to the array of LESs comprises at least one of a lateral offset, a vertical offset, or a distance offset between the array of photodiodes and the array of LESs.

In some additional examples, the assembly includes one or more transimpedance amplifiers configured to amplify the photo-induced currents from the array of photodiodes.

In some cases, the array of LESs comprises an array of vertical-cavity surface-emitting lasers.

In accordance with another example embodiment, a method for monitoring output of a light emitting source (LES) is provided. In some examples, the method includes measuring a photo-induced current induced in one or more photodiodes in an array of photodiodes, arranged to receive light reflected off of an array of lenses, wherein the light is emitted by an array of LESs configured to emit light towards the array of lenses, and wherein each photodiode is configured to generate the photo-induced current in response to receipt of the light reflected off the lenses, and determining a change in operational status of one or more of the LESs based on the photo-induced currents.

In some examples of the method, the array of LESs and the array of photodiodes form a coupled pair, and the method further includes receiving a value indicative of a power consumption of each LES in the array of LESs, correlating the power consumption of each LES with a measured photo-induced current in each photodiode. The method also includes determining a coupling matrix, and determining an inverted matrix by inverting the coupling matrix.

In some examples, the method further includes determining a photo-induced current matrix from updated measured photo-induced currents from each photodiode, and multiplying the inverted matrix and the photo-induced current matrix to form a LES output matrix, wherein the LES output matrix represents an ongoing light output from each LES.

In some cases, determining a change in the operational status of one or more of the LESs based on the photo-induced currents further includes determining, from the LES output matrix, one or more LESs experiencing a failure event based on an ongoing light output lower than a predetermined expected value.

In some additional examples, the failure event comprises a failing LES and the lower ongoing light output comprises a light output lower than a predetermined expected value.

In some examples of the method, the failure event comprises a failed LES and the lower ongoing light output comprises no light output.

In some examples, each photo-induced current comprises an amplified photo-induced current.

In some cases, the array of LESs comprises an array of vertical-cavity surface-emitting lasers.

The above summary is provided merely for purposes of summarizing some example embodiments to provide a basic understanding of some aspects of the invention. Accordingly, it will be appreciated that the above-described embodiments are merely examples and should not be construed to narrow the scope or spirit of the invention in any way. It will be appreciated that the scope of the invention encompasses many potential embodiments in addition to those here summarized, some of which will be further described below.

### BRIEF DESCRIPTION OF THE DRAWING(S)

Having thus described the invention in general terms, reference will now be made to the accompanying drawings, which are not necessarily drawn to scale, and wherein:

FIG. 1 illustrates a side view of an assembly for monitoring output of a light emitting source according to an example embodiment;

FIG. 2 illustrates a perspective side view of an assembly for monitoring output of a light emitting source according to an example embodiment;

FIG. 3 illustrates a perspective view of an assembly for monitoring output of a light emitting source according to an example embodiment;

FIG. 4A illustrates a side view of an assembly for monitoring output of a light emitting source according to an example embodiment;

FIGS. 4B-4C illustrate top views of an assembly for monitoring output of a light emitting source according to an example embodiment;

FIG. 5A illustrates a power consumption matrix according to example embodiments;

FIG. 5B illustrates a photo-induced current matrix according to example embodiments;

FIG. 5C illustrates a coupling matrix according to example embodiments;

FIG. 6 illustrates an example block diagram for a controller monitoring output of a light emitting source according to an example embodiment;

FIG. 7 illustrates a transimpedance amplifier according to an example embodiment;

FIG. 8A is a flowchart illustrating an example method for monitoring output of a light emitting source according to an example embodiment; and

FIGS. 8B-8C are flowcharts illustrating additional example methods for monitoring output of a light emitting source according to example embodiments.

### DETAILED DESCRIPTION OF THE INVENTION

The present invention now will be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout. As used herein, relational terms such as “above,” “below,” “parallel,” etc. are used for explanatory purposes in the examples provided below to describe the relative position of certain components or portions of components to other components or portions.

As noted above, operators of optical networks often desire to know the operational status of the optical communication components. One way to verify that these components are functioning properly is to measure the light that is coming out of the light-producing components. Conventional methods for measuring the light require a tap or other structures, such as altered lenses, to divert light towards a photodiode to measure the light produced. Such methods automatically result in lower light (as much as 30% lower) for use in the optical functions requiring the light. Additionally, designing and updating structures, including lens structures, to redirect light for measurement can be expensive and time consuming.

To optimize the use of the light emitted by the light producing components and to reduce the expense of designing and implementing light redirecting structures, the inventors have designed an assembly and method to determine the light output by light emitting sources in a communication network by measuring light reflected off of the lens without the use of additional structures.

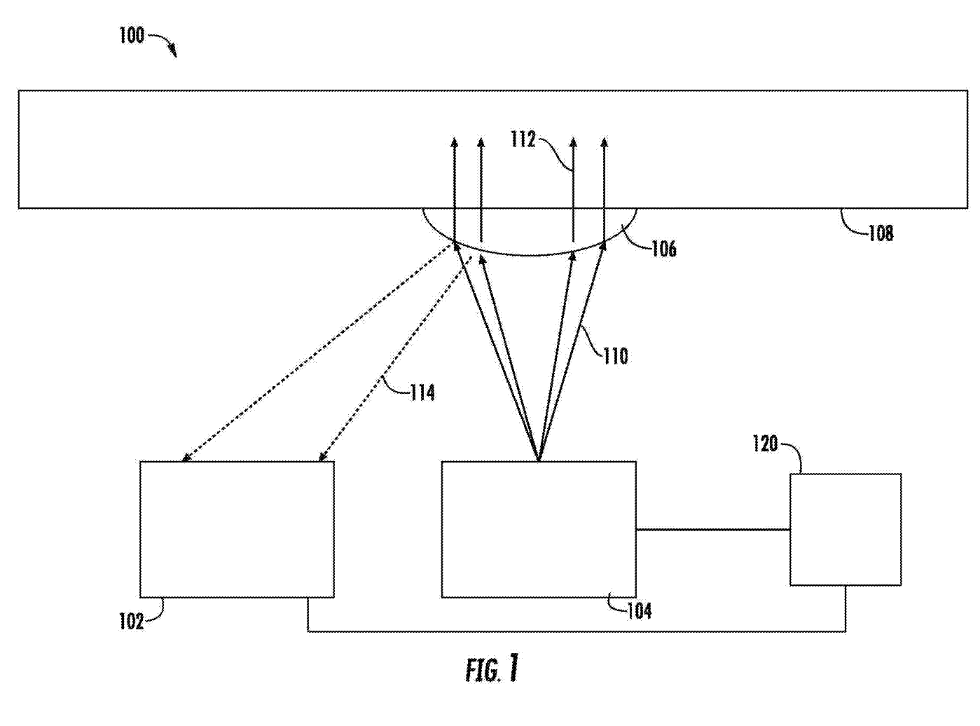

Turning now to FIG. 1, FIG. 1 illustrates an assembly 100 for monitoring output of a light emitting source according to an example embodiment. The assembly may be a part of an optical transmitter and/or an optical transceiver used for optical communication such as fiber optic communication.

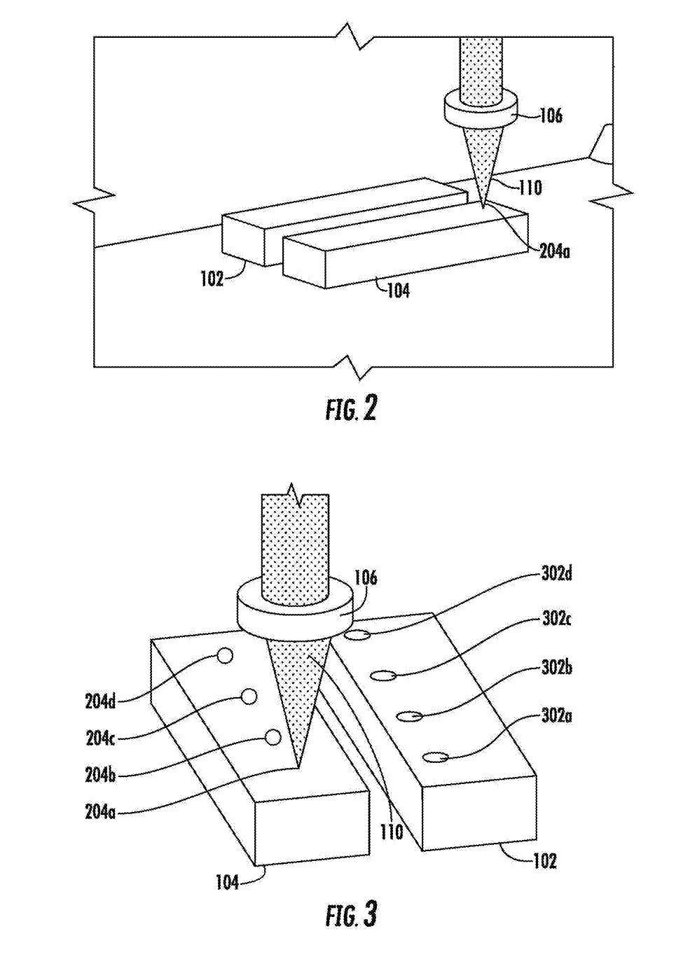

As shown, the assembly 100 may include an array of light emitting sources (LESs) 104. The array of LESs 104 may be configured to emit light towards an array of lenses 108, such that each LES in the array of LESs 104 emits light 110 towards a lens 106. For example, as further illustrated in FIGS. 2 and 3, a LES 204a, in the array of LESs 104, emits light 110 towards a lens 106 in the array of lenses 108.

As shown in FIGS. 1 and 2 the array of lenses 108 may comprise an array of one or more lenses such as an array of polyetherimide lenses or ULTEM lenses. In some embodiments, the one or more lenses may comprise any common lens material. The array of lenses 108 may be positioned above the array of LESs 104 and an array of photodiodes 102. In some examples, the lens is positioned above the array of LESs or in line with the light emitted from the LES. In some examples, the LESs in the array of LESs may comprise one or more vertical-cavity surface-emitting lasers (VCSELs). Some embodiments may utilize other light sources, such as DFB lasers (distributed feedback lasers) and LED's (light emitting diodes) among other light emitting sources whose light may reflect off a lens into a photodiode.

According to some embodiments, a certain amount of the light 110 emitted towards the lens 106 will be reflected off of the lens. In an example using a polyetherimide lens, the surface of the lens 106 in the array of lenses 108, may reflect approximately 6% of the light 110 emitted towards it from a light source in the array of LESs 104. The unreflected light 112 will pass through the lens 106 and can be used for further functions, such as fiber optic communication.

Referring back to FIG. 1, the assembly 100 also includes an array of photodiodes 102 positioned to receive light reflected off of the array of lenses 108. For example, a photodiode in the array of photodiodes 102 may be positioned to receive reflected light, such as reflected light 114. As shown in FIGS. 2 and 3 the array of photodiodes 102 may be positioned parallel to the array of LESs 104. For example, as shown in FIG. 3, the array of photodiodes 102 may be positioned such that photodiode 302a optimally receives a light reflected off a corresponding lens 106, which receives light from the corresponding LES 204a. In the same manner, the array of photodiodes 102 is positioned such that the photodiodes 302b, 302c, and 302d may also be positioned to receive the light reflected off of other lenses (not shown) in the array of lenses 108 (FIG. 1), which receive light from the corresponding LESs 204b, 204c, and 204d, respectively.

Due to the nature of light and reflections, the photodiodes 302a-302d will be affected by a certain level of crosstalk, or light reflected off of the other lens in the array of lenses. For example, when the array of photodiodes 102 is functioning normally, the photodiode 302b will receive some level of light reflected off of the lens 106 as shown in FIG. 3. In this instance the intensity of the light received by the photodiode 302b from the lens 106 will be lower than the intensity of the light received by photodiode 302a from the lens 106, but higher than the level received by the photodiodes 302c and 302d. For example, the photodiode 302b may receive −3.9 decibels (dB) of crosstalk, the photodiode 302c may receive −14.6 dB of crosstalk, and the photodiode 302d may receive −50 dB of crosstalk from the light reflected off of the lens 106. Since this crosstalk can be large, it must be taken into account when interpreting and correlating the currents produced by the photodiodes in the photodiode array.

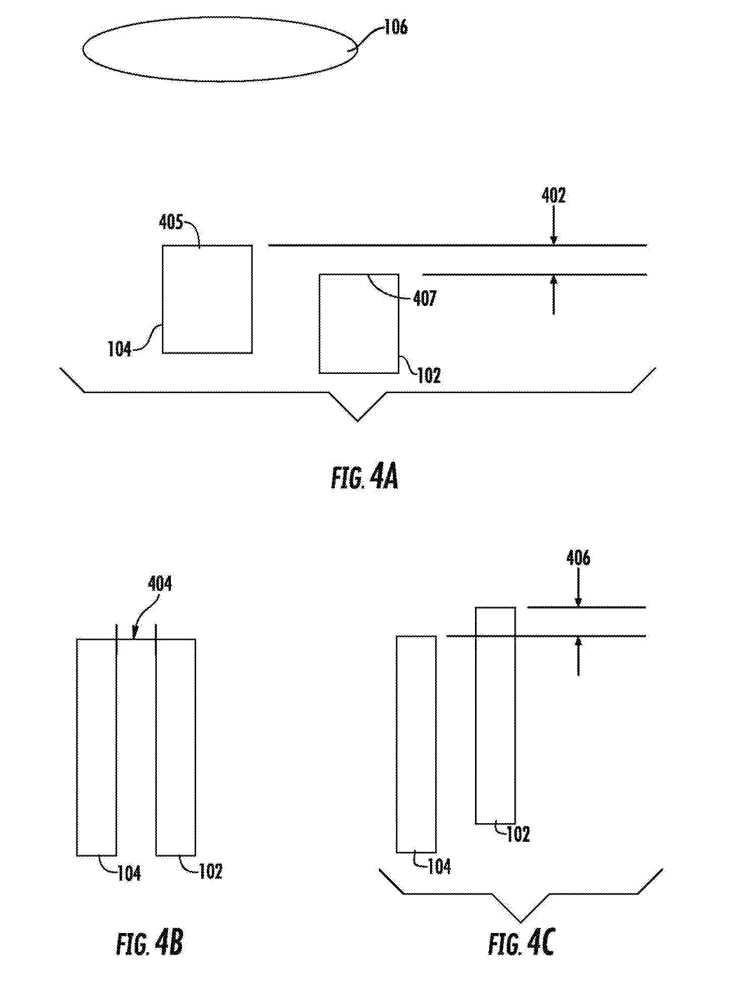

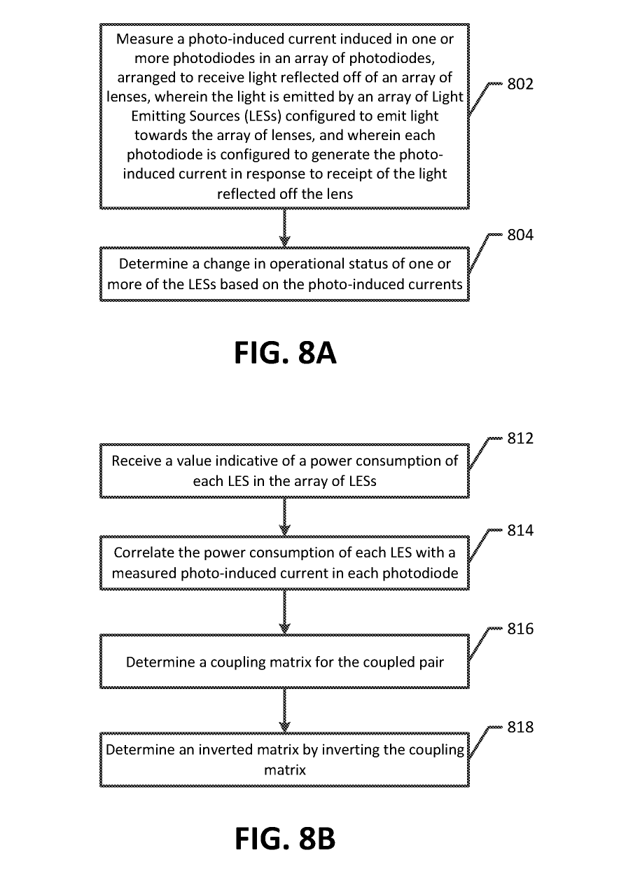

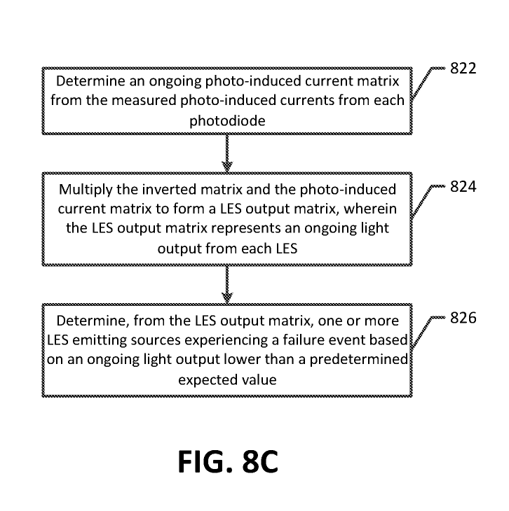

To optimize the positioning of the array of LESs 104 and the array of photodiodes 102, the inventors have discovered that certain position parameters should be followed, as shown in FIGS. 4A-4C. These parameters aid in the avoidance of increased uncertainty in the operations described in FIGS. 8A-8C. For example, as shown in the side view depicted in FIG. 4A, there may be a vertical offset 402 between an upper surface 405 array of LESs 104 and an upper surface 407 of the array of photodiodes 102, where upper surface of the array of photodiodes 102 is below the upper surface of array of LESs 104 (or further away from the lens 106 than the array of photodiodes 102). The array of LESs and photodiodes may be configured to have a maximum lower vertical offset of 40 micrometers. In an example where the array of photodiodes 102 is positioned above the array of LESs 104 (or closer to lens 106 than the array of LESs 104), which is opposite to the positions shown in FIG. 4A, the assembly should include a maximum higher vertical offset of 60 micrometers.

Turning to FIG. 4B, which looks down on the array of LESs and the array of photodiodes, a distance offset 404 between the array of photodiodes 102 and the array of LESs 104 may optimally be less than 100 micrometers and may comprise a maximum distance offset of 125 micrometers. Likewise, FIG. 4C (also a top view) illustrates a lateral distance offset 406 between the corresponding ends of the arrays, where the lateral offset 406 comprises a maximum lateral offset of 30 micrometers.

Turning again to FIGS. 1-3, the array of photodiodes 102 may form a coupled pair with the array of LESs 104. Thus, when optimally positioned, the coupled pair may form a coupling where the current produced in a photodiode (such as the photodiode 302a) corresponds to the current produced by a respective LES (such as the LES 204a). For example, the LES 204a may consume approximately 7 milliamps (mA) to produce light 110 (the light output of light 110 may be approximately 4 milliwatts (mW)), and reflected light 114. The reflected light 114 may then induce a current in the corresponding photodiode 302a of approximately 560 nanoamps (nA) in the photodiode. In this case, the unit-less coupling factor would be 8*10⁻⁵ (amps-PD to amps-VCSEL). In some examples, the power-current curve for a LES (e.g. a VCSEL) can be represented as approximately 0.3 output Watts over the input Watts. In this case, the responsivity of the a photodiode, such as the photodiode 302a will be approximately 0.6 A/W, which can be rewritten as power coupling factor of 6.7*10⁻⁵ (W/W) (power impinging to the photodiode to power into the LES (e.g. a VCSEL)).

Turning again to FIG. 1, the assembly 100 also includes a controller 120 in communication with the array of LESs 104 and the array of photodiodes 102. In some examples, the controller 120, may comprise a microcontroller or integrated circuit configured to perform the functions described in FIGS. 8A-C.

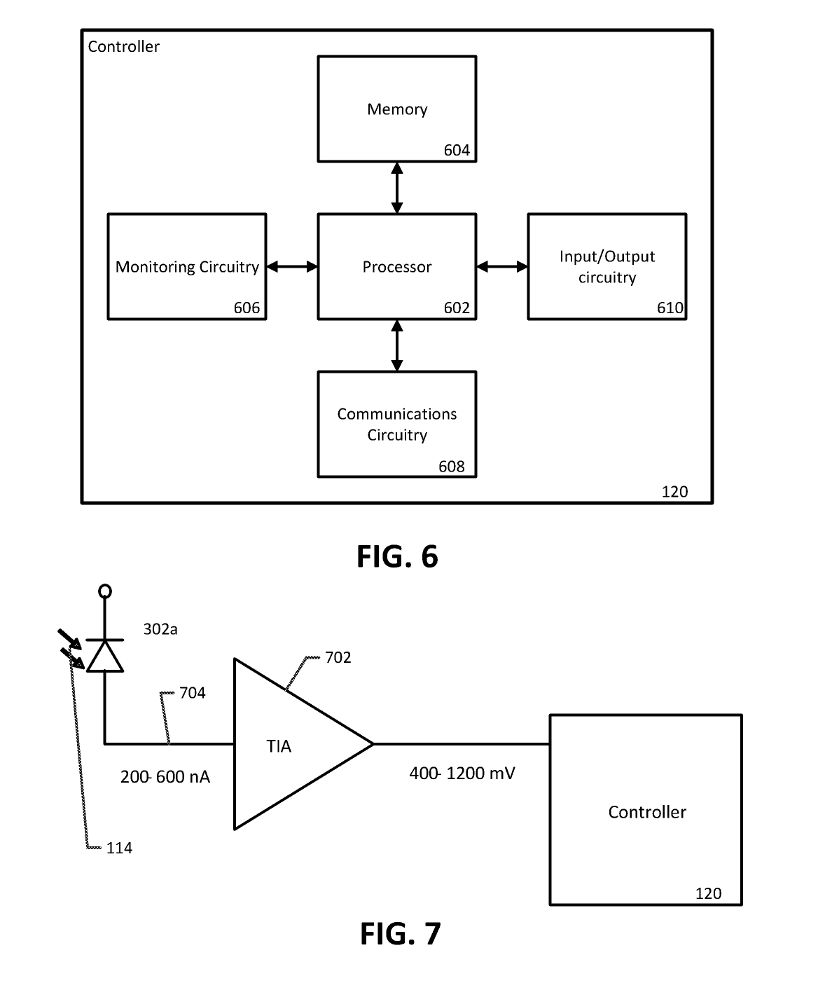

For example FIG. 6 shows an example controller 120 of assembly 100. The controller 120 may include a processor 602, in communication with a memory 604. The processor 602 may be configured in conjunction with monitoring circuitry 606, input/output circuitry 610, and communications circuitry 608 to perform the operations described in FIGS. 8A-8C. It should be understood that the separate blocks of controller 120 shown in FIG. 6 are for illustration, and in some examples, the circuitry of controller 120 may be embodied as an integrated circuit, such that each of the blocks are embodied in the same circuitry and the functions are performed in conjunction with software.

As shown in FIG. 7, the assembly may also further include one or more transimpedance amplifiers (TIA) placed between the array of photodiodes 102 and the controller 120. For example, a TIA 702 may receive a current 704 induced at photodiode 302a by reflected light 114 of approximately 200-600 nanoamps and convert the current to a voltage of approximately 400-1200 millivolts. In some examples, this will aid in evaluation and usage of very low induced current outputs from the photodiodes at the controller. In some examples, a TIA 702 is positioned in line between each of the photodiodes in the array of photodiodes 102 and the controller 120.

FIG. 8A is a flowchart illustrating an example method for monitoring output of a LES. As shown in block 802, monitoring circuitry, such as monitoring circuitry 606 in the controller 120, may be configured to measure a photo-induced current induced in one or more photodiodes in an array of photodiodes (such as the array of photodiodes 102), arranged to receive light (such as the light 114) reflected off of an array of lenses (such as the array of lenses 108), wherein the light is emitted by an array of LESs (such as the array of LESs 102) configured to emit light (such as the light 110) towards the array of lenses, and where each photodiode is configured to generate the photo-induced current in response to receipt of the light reflected off the lens.

As shown in block 804, monitoring circuitry 606 in the controller 120 may be configured to determine a change in the operational status of one or more of the LESs based on the photo-induced currents. In some examples, the change in operational status may be the failure of one or more LES in the array of LES 104. This step is described in more detail in relation to FIG. 8C.

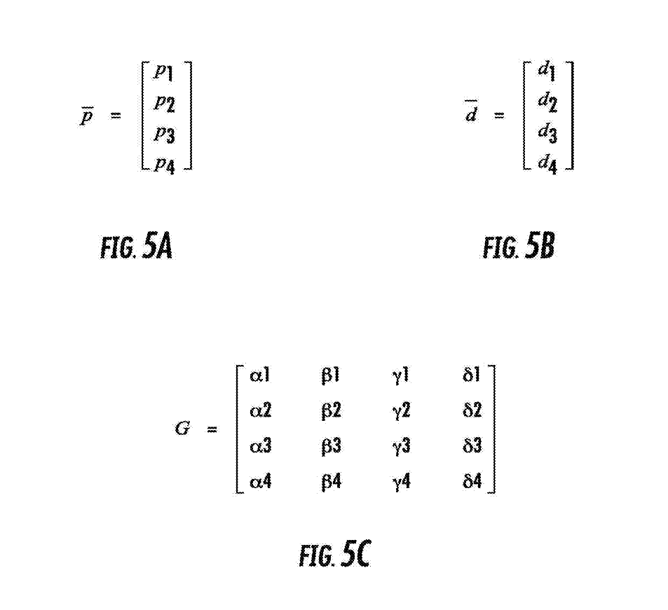

FIG. 8B is a flowchart illustrating an additional example method for monitoring the output of a LES. As shown in block 812, input/output circuitry 610 of the controller 120 may be configured to receive a value indicative of a power consumption of each LES in the array of LESs. In some examples, the controller 120 may be configured to store the power consumption of the LESs, in the form of the current to the LES, as a matrix p̅ as shown in FIG. 5A. For example, p₁ may correspond to the power consumption of the LES 204a; p₂ may correspond to the power consumption of the LES 204b; p₃ may correspond to the power consumption of the LES 204c; and p₄ may correspond to the power consumption of the LES 204d. In some examples, the controller 120 may be also configured to store the induced current of the photodiodes as an array d̅ as shown in FIG. 5B. For example, d₁ may correspond to the induced current from the photodiode 302a; d₂ may correspond to the induced current from the photodiode 302b; d₃ may correspond to the induced current from the photodiode 302c; and d4 may correspond to the induced current from the photodiode 302d.

As shown in block 814, the monitoring circuitry 606 in the controller 120 may be configured to correlate the power consumption of each LES with a measured photo-induced current in each photodiode. In some examples, the array of photodiodes and the array of LESs form a coupled pair, and the correlation may include a determination that the photo-induced current is equal to the power consumption of the LESs multiplied by a coupling matrix G as shown in Equation 1.

d̅=Gp̅ Equation 1:

As shown in block 816, the monitoring circuitry 606 in the controller 120 may be configured to determine a coupling matrix for the coupled pair. For example, a coupling matrix such as coupling matrix G shown in FIG. 5C may be determined by supplying current to each of the LESs in known patterns (e.g. p1, p2, p3 . . . pn), to represent the whole dimensional space offered by the array of a number of LESs, in the array of LESs individually and measuring the amount of photo-induced current at each photodiode. For example, α1 may be photo-induced current at photodiode 302a when the LES 204a is individually powered. Likewise, α2, α3, and α4, may be the photo-induced currents at photodiodes 302b, 302c, and 302d respectively. Thus, powering the LES 204b would induce currents β1, β2, β3, and β4 at the photodiodes 302a, 302b, 302c, and 302d respectively, when the LES 204a is individually powered. In the same way, powering the LES 204c would induce currents γ1, γ2, γ3, and γ4 at the photodiodes 302a, 302b, 302c, and 302d, respectively. Finally, powering the LES 204d would induce currents δ1, δ2, δ3, and δ4 at the photodiodes 302a, 302b, 302c, and 302d, respectively.

As shown in block 816, the monitoring circuitry 606 in the controller 120 may be configured to determine an inverted matrix by inverting the coupling matrix. In some embodiments, in order to determine the output of the LESs from a measurement of the photo-induced currents, the coupling matrix G must be inverted as shown in Equation 2.

G⁻¹d̅=p̅ Equation 1:

In some examples, the monitoring circuitry 606 is also configured to store the coupling matrix G and/or the inverted matrix G⁻¹ in the memory 604 for later use or for use as a standard coupling or inverted matrix. In some examples, the operations of FIG. 8B may be performed once at the beginning of the use of the assembly, such that the coupling matrix and/or the inverted matrix is stored in the memory 604 and used continuously during the monitoring of the output of the LESs. In some examples, the coupling matrix may be determined for a type or set of assemblies 100, such as a set of mass produced assemblies 100, wherein each of the assemblies of the set is configured to share the same coupling matrix. In this instance, each individual assembly of the type would not need to perform the functions of FIG. 8B and can instead rely on a stored standard coupling matrix or standard inverted coupling matrix.

FIG. 8C is a flowchart illustrating an additional example method for monitoring the output of a LES and specifically for determining a change in the operational status of one or more of the LESs based on the photo-induced currents. As shown in block 822, the monitoring circuitry 610 of the controller 120 may be configured to determine an ongoing/updated photo-induced current matrix from the measured photo-induced currents from each photodiode. For example, the ongoing/updated photo-induced current matrix may take the same form as the matrix d̅ shown in FIG. 5B and may represent ongoing or periodically updated photo-induced currents from the photodiodes of the array of photodiodes 102.

As shown in block 824, the monitoring circuitry 610 of the controller 120 may be configured to multiply the inverted matrix G⁻¹ described above and the photo-induced current matrix to form a LES output matrix, where the LES output matrix represents an ongoing or periodically updated light output from each LES. In some examples, the inverted matrix G⁻¹ is the inverted matrix G⁻¹ described in the operations of FIG. 8B. In another example, the inverted matrix may be a standard inverted matrix stored in the memory 604. Accordingly, in some examples, the LES output matrix may take the form of the matrix p̅ shown in FIG. 5A.

As shown in block 826, the monitoring circuitry 610 of the controller 120 may be configured to determine, from the LES output matrix, one or more LESs experiencing a failure event based on a lower ongoing light output of the LES as compared to a previously determined or expected light output for the same LES. In some examples, the failure event may be a failing LES, where the lower ongoing light output comprises a light output that is lower than a predetermined value. The predetermined value may, for example, be an expected output for the particular type of LES (e.g., based on its design specifications),taking into account the amount of current consumed by the LES, and/or the temperature of the LES. In some cases, the predetermined value may be provided by the manufacturer of the LES, whereas in other cases the predetermined value may be calculated or experimentally derived based on various factors such as the current consumed by the LES, the temperature of the LES, and/or other external factors that may affect the power consumption. For example, in some cases, the predetermined value may be an average of a historical light output for the given LES over a period of time during which the LES is in operation (e.g., the previous month). Thus, for a failing LES, the LES output matrix may show one of the LESs as outputting less light than expected. For example, if the LES 204a is producing less light than expected, such as an output of 0.8 μA where the predetermined or expected value is 1 μA, p1 in FIG. 5A would be lower than expected. In another example, the failure event may be a failed LES where the lower ongoing light output comprises no light output. In this case, the LES output matrix would show that one of the LESs is not outputting light. For example, if LES 204a is producing no light, p1 in FIG. 5A would be approximately 0. Accordingly, a failing LES may be an LES that is performing, but is not performing in an optimal manner (e.g., not meeting design specifications), whereas a failed LES may be an LES that is no longer performing (e.g., no longer operational).

In some examples, upon detection of the failure event, the communication circuitry 608 in the controller 120 may be configured to transmit a notification warning to an operator that a failure event has been detected at a particular LES.

Thus the operations and assembly described herein provide a reliable and efficient method to monitor a failure event of a light emitting source. For example, if a VCSEL in an optical transceiver in a fiber optic network continues to consume power in the form of electric current but the light output from the VCSEL is decreasing, the induced current in the photodiodes described herein will decrease, and the controller in the assembly will determine based on the coupled pairing which of the VCSELs is experiencing the decreased output. Upon determination of the problem in the VCSEL, the controller 120 will notify an operator of the affected optical transceiver. This will provide the operator of the fiber optic network early notification of potential failures in the network and allow for preventative or ongoing maintenance.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

1. An assembly for monitoring output of a light emitting source (LES) comprising:
an array of lenses;
an array of LESs, wherein each LES is configured to emit light towards a lens in the array of lenses;
an array of photodiodes, arranged to receive light reflected off of the array of lenses, wherein each photodiode is configured to generate a photo-induced current in response to receipt of the light reflected off the array of lenses, wherein the light is reflected off of a transmissive portion of one or more lenses of the array of lenses; and
a controller configured to:
measure the photo-induced current from each photodiode in the array of photodiodes; and
determine a change in operational status of one or more of the LESs based on the photo-induced currents.

2. The assembly of claim 1,
wherein the array of LESs and the array of photodiodes form a coupled pair; and
wherein the controller is further configured to:
receive a value indicative of a power consumption of each LES;
correlate the power consumption of each LES with a measured photo-induced current in each photodiode;
determine a coupling matrix for the coupled pair; and
determine an inverted matrix by inverting the coupling matrix.

3. There assembly of claim 2, wherein the controller is further configured to:
determine a photo-induced current matrix from updated measured photo-induced currents from each photodiode; and
multiply the inverted matrix and the photo-induced current matrix to form a LES output matrix, wherein the LES output matrix represents an ongoing light output from each LES.

4. The assembly of claim 3, wherein the controller is further configured to:
determine, from the LES output matrix, one or more LESs experiencing a failure event based on an ongoing light output lower than a predetermined expected value from the one or more LESs.

5. The assembly of claim 4, wherein the failure event comprises a failing LES and wherein the lower ongoing light output comprises a light output lower than a predetermined expected value.

6. The assembly of claim 4, wherein the failure event comprises a failed LES and wherein the lower ongoing light output comprises no light output.

7. The assembly of claim 1, wherein a position of the array of photodiodes relative to the array of LESs comprises at least one of a lateral offset, a vertical offset, or a distance offset between the array of photodiodes and the array of LESs.

8. The assembly of claim 1, further comprising one or more transimpedance amplifiers configured to amplify the photo-induced currents from the array of photodiodes.

9. The assembly of claim 1, wherein the array of LESs comprises an array of vertical-cavity surface-emitting lasers.

10. A method for monitoring output of a light emitting source (LES) comprising:
measuring a photo-induced current induced in one or more photodiodes in an array of photodiodes, arranged to receive light reflected off of an array of lenses, wherein (a) the light is emitted by an array of LESs configured to emit light towards the array of lenses, (b) each photodiode is configured to generate the photo-induced current in response to receipt of the light reflected off the lenses, and (c) the light is reflected off of a transmissive portion of one or more lenses of the array of lenses; and
determining a change in operational status of one or more of the LESs based on the photo-induced currents.

11. The method of claim 10, wherein the array of LESs and the array of photodiodes form a coupled pair, the method further comprising
receiving a value indicative of a power consumption of each LES in the array of LESs;
correlating the power consumption of each LES with a measured photo-induced current in each photodiode;
determining a coupling matrix; and
determining an inverted matrix by inverting the coupling matrix.

12. The method of claim 11, further comprising:
determining a photo-induced current matrix from updated measured photo-induced currents from each photodiode; and
multiplying the inverted matrix and the photo-induced current matrix to form a LES output matrix, wherein the LES output matrix represents an ongoing light output from each LES.

13. The method of claim 12, wherein determining a change in the operational status of one or more of the LESs based on the photo-induced currents further comprises:
determining, from the LES output matrix, one or more LESs experiencing a failure event based on an ongoing light output lower than a predetermined expected value.

14. The method of claim 13, wherein the failure event comprises a failing LES and wherein the lower ongoing light output comprises a light output lower than a predetermined expected value.

15. The method of claim 13, wherein the failure event comprises a failed LES and wherein the lower ongoing light output comprises no light output.

16. The method of claim 10, wherein each photo-induced current comprises an amplified photo-induced current.

17. The method of claim 10, wherein the array of LESs comprises an array of vertical-cavity surface-emitting lasers.
